(19) United States
(12) Patent Application Publication
(10) Pub. No.: US 2002/0118528 A1
(43) Pub. Date: Aug. 29, 2002

(54) Substrate layout method and structure for reducing cross talk of adjacent signals

(76) Inventors: Bor-Ray Su, Taipei (TW); Chin-Chih Li, Taipei (TW)

Correspondence Address: Michael D. Bednarek, SHAWPITTMAN, 1650 Tysons Boulevard, McLean, VA, 22102-4859, US

(21) Appl. No.: 09/810,558

(22) Filed: Mar. 19, 2001

(30) Foreign Application Priority Data
Dec. 15, 2000 (TW) 089126860

(51) Int. Cl. H05K 7/14; H05K 7/18

(52) U.S. Cl. 361/800

(57) ABSTRACT

The invention provides a substrate layout method and structure of a ball grid array to reduce cross talk of adjacent signals. The substrate comprises a plurality of signal pads formed on a die, a ring around the die, and a plurality of signal fingers around the ring. The substrate layout method for reducing cross talk of adjacent signals is as follows: First, forming a guard pad between two adjacent signal pads. Second, forming a guard finger between two adjacent signal fingers. Next, forming a bonding wire to connect the guard pad to the ring. Then, forming another bonding wire to connect the ring to the guard finger. Subsequently, forming a guard trace to connect the guard finger to a via at the edge of the substrate, and connecting the guard trace to a short-circuiting place through the via.

### REFERENCE TO RELATED APPLICATION

The present application claims priority from Taiwan Application No. 089126860, entitled “Substrate Layout Method and Structure for Reducing Cross Talk of Adjacent Signals,” filed on Dec. 15, 2000.

### BACKGROUND OF THE INVENTION

1. Field of the Invention

This invention relates to a substrate layout method and structure of a ball grid array(BGA), and more particularly to a substrate layout method and structure of a ball grid array for reducing cross talk of adjacent signals.

2. Description of the Related Art

To meet the demands of high speed and high performance for IC (Integrated Circuit) products, new package technology such as BGA (Ball Grid Array) is rapidly developed. Concerning the structure of BGA, refer to FIG. 1. FIG. 1 is a cross section of a prior art BGA. As shown in FIG. 1, all signals go from pads 12 on a die 10 to fingers 18 or rings 20 on the substrate 16 through bonding wires 14. The fingers 18 pass signals through vias 24 to solder balls 26 under the substrate 16 by traces 22, and the rings 20 pass signals through vias 24 to a power plane or a ground plane of the substrate 16 by traces 22. The power plane and the ground plane are used for providing a power signal and a ground signal respectively. As the signal frequency increases, cross talk between adjacent signals becomes stronger. In order to avoid cross talk from affecting the transfer quality of critical signals (such as clocks or signals sensitive to noise) cross talk interference must be considered when doing the IC design.

Currently, a solution for reducing cross talk is to increase distance of adjacent signals. As shown in FIG. 2a, two temporary traces 30 are added when the IC layout is being processed. After the IC layout is finished, as shown in FIG. 2b, two temporary traces 30 are removed. Thus, a distance between the clock trace 28 and the adjacent normal signal trace 32 is as follows:

CN=TW+2TT

Wherein the TW is the width of a single trace, and the TT is the closest distance of two adjacent traces.

### SUMMARY OF THE INVENTION

The object of the present invention is to provide a substrate layout method and structure for reducing cross talk of adjacent signals. After finishing the IC layout, designers utilize the available temporary traces to effectively avoid cross talk of the adjacent signals without increasing distance between traces or affecting the yield of the IC products.

In one embodiment, the substrate layout method for reducing cross talk of two adjacent signals is as follows: First, forming a guard pad between two adjacent signal pads. Second, forming a guard finger between two adjacent signal fingers. Next, forming one bonding wire to connect the guard pad to the ring. Then, forming another bonding wire to connect said ring to the guard finger. Subsequently, forming a guard trace to connect the guard finger to a via at the edge of the substrate, and connecting the guard trace to a short-circuiting place through the via. In the embodiment, the substrate is a ball grid array, and the bonding wires is selected from the group consisting of a power and ground bonding wire. The ring is selected from the group consisting of a power and ground ring. The short-circuiting place is selected from the group consisting of a power and ground plane of the substrate; if there is no power or ground plane, the short-circuiting place is selected from the group consisting of a power and ground solder ball under the substrate.

In another embodiment, the substrate layout method for reducing cross talk of two adjacent signals is as follows: First, forming a guard finger between two adjacent signal fingers. Second, forming a bonding wire to connect a ring to the guard finger. Next, forming a guard trace to connect the guard finger to a via at the edge of the substrate and connecting the guard trace to a short-circuiting place through the via. In the embodiment, the substrate is a ball grid array, and the bonding wire is selected from the group consisting of a power and ground bonding wire. The ring is selected from the group consisting of a power and ground ring. The short-circuiting place is selected from the group consisting of a power and ground plane of the substrate; if there is no power or ground plane, the short-circuiting place is selected from the group consisting of a power and ground solder ball under the substrate.

The foregoing is a brief description of some deficiencies in the prior art and advantages of this invention. Other features, advantages and embodiments of the invention will be apparent to those skilled in the art from the following description, accompanying drawings and appended claims.

### BRIEF DESCRIPTION OF DRAWINGS

The following detailed description, given by way of examples and not intended to limit the invention to the embodiments described herein, will be best understood in conjunction with the accompanying drawings in which:

FIG. 1 is a cross section of a prior art BGA;

FIG. 2a is a schematic diagram showing states where two temporary traces are added to the IC layout;

FIG. 2b is a schematic diagram showing states where two temporary traces are removed from the IC layout;

FIG. 3a is the first simulation of cross talk influence on rectangular wave signal due to the temporary traces.

FIG. 3b is the second simulation of cross talk influence on rectangular wave signal due to the temporary traces.

FIG. 3c is the third simulation of cross talk influence on rectangular wave signal due to the temporary traces.

FIG. 4a is a schematic diagram of one embodiment in accordance with this invention;

FIG. 4b is a cross section of the substrate having a power plane or a ground plane in FIG. 4a;

FIG. 4c is a cross section of the substrate having neither power plane nor ground plane in FIG. 4a;

FIG. 5 is a flow chart of substrate layout method in FIG. 4a;

FIG. 6 is a schematic diagram of another embodiment in accordance with this invention; and

FIG. 7 is a flow chart of substrate layout method in FIG. 6.

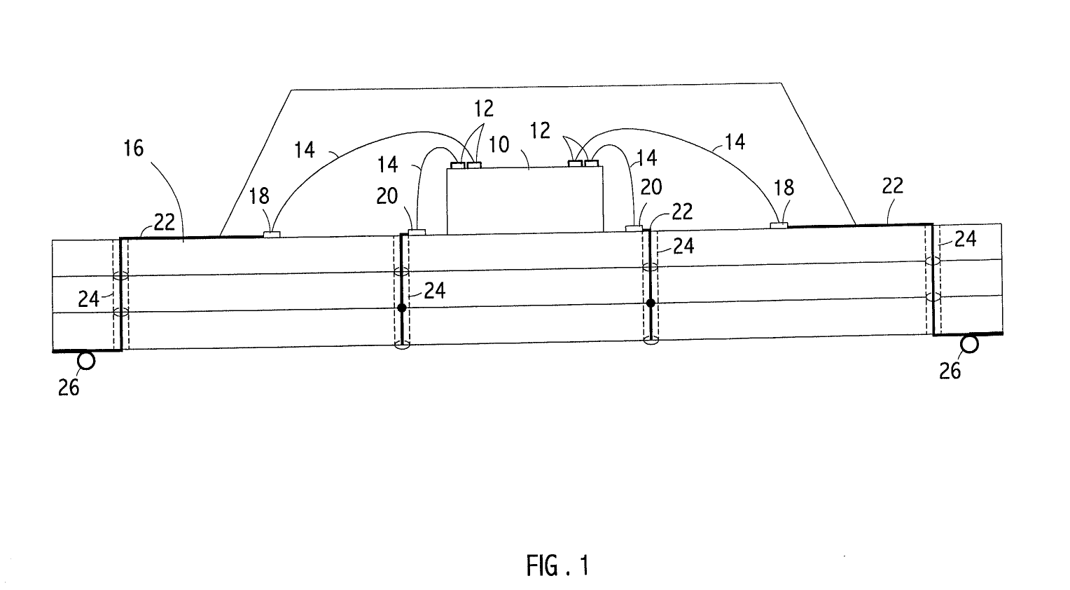

### DETAILED DESCRIPTION OF THE INVENTION

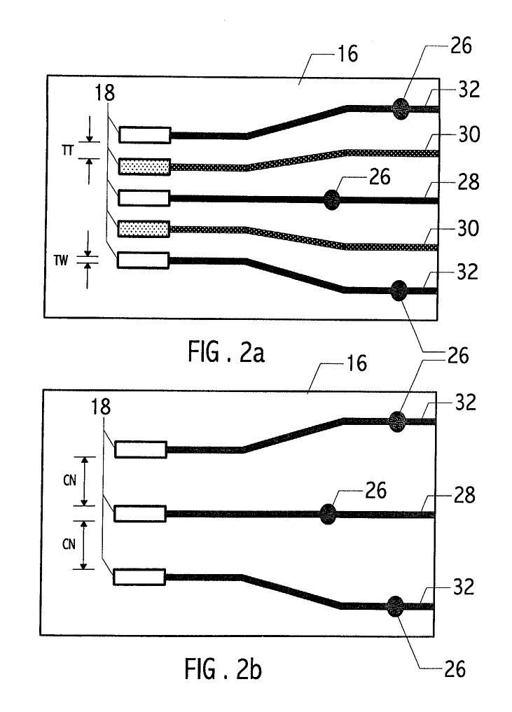

From FIG. 2a and FIG. 2b, when IC layout is being processed, two temporary traces 30 are added to increase distance between the clock trace 28 and the normal signal trace 32 to reduce cross talk between the clock and the normal signal. However, after finishing the IC layout, the two temporary traces 30 are removed and not used anymore. In fact, in view of clock trace 28 the two temporary traces 30 can also be guard traces screening against cross talk between the clock and the normal signal. Thus, the present invention provides a design that utilizes the available temporary traces rather than increasing extra distance to avoid cross talk of the adjacent signals more effectively after the IC layout is finished.

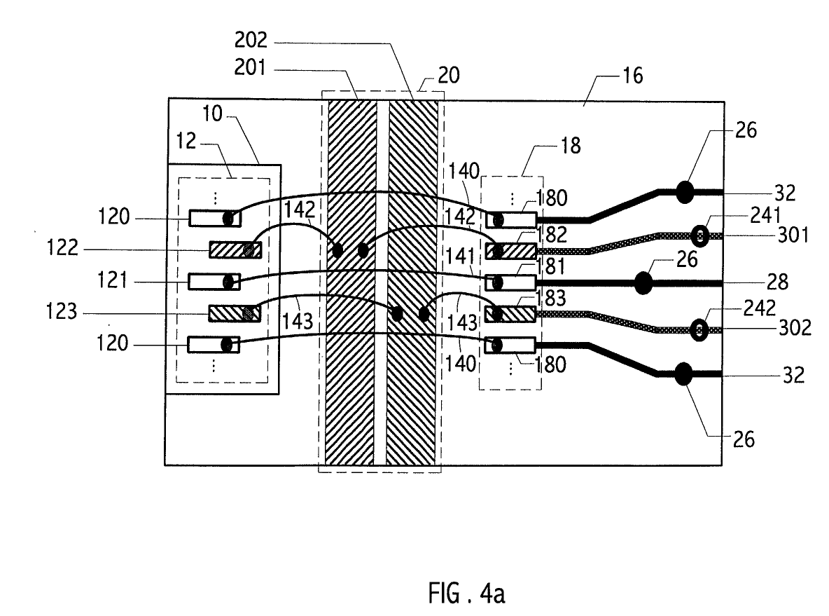

One embodiment of the present invention is described below in connection with FIG. 3a, 3b and 3c. According to the layout of guard traces on a BGA substrate, simulating and finding the best screening design against cross talk, including four conditions: without guard trace, both side of guard trace shorten to ground, only one side of guard trace shorten to ground, and both side of guard trace are open. FIG. 3a is a simulation of cross talk influence on an ideal rectangular wave signal where the rising time is 0 ns due to the temporary traces. FIG. 3b is a simulation of cross talk influence on a rectangular wave signal where the rising time is 0.5 ns due to the temporary traces. FIG. 3c is a simulation of cross talk influence on a rectangular wave signal where the rising time is 1 ns due to the temporary traces. According to the simulation results, when both side of guard trace is shorten to ground, the maximum and average voltage variation of the rectangular wave signal are minimal. Thus, it can provide the best screening performance against cross talk.

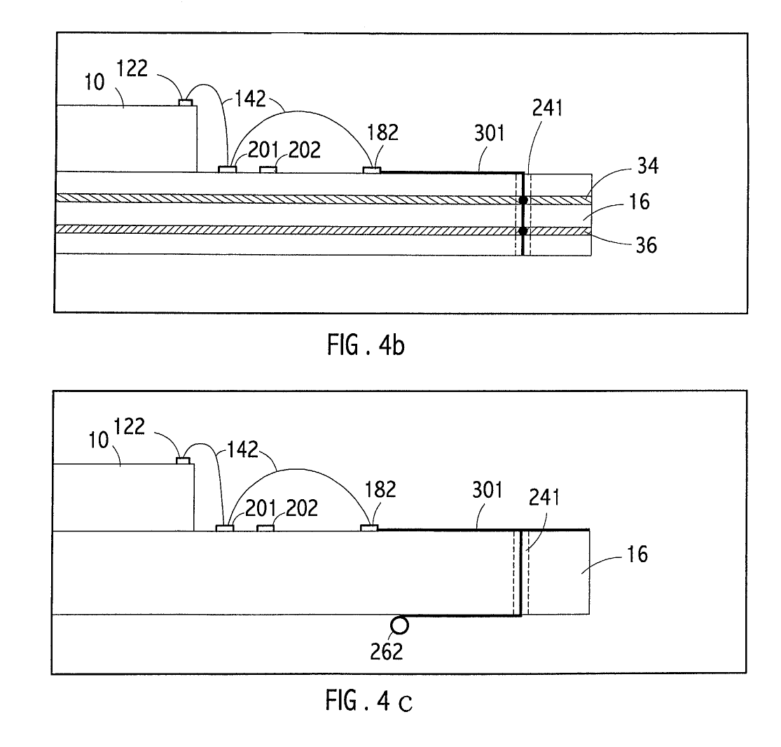

Refer to FIG. 4a, 4b and 4c. As shown in FIG. 4a, there are normal signal pad 120, clock pad 121, power pad 122 and ground pad 123 etc. on the die 10 of BGA substrate, wherein power pad 122 and ground pad 123 are formed between normal signal pad 120 and clock pad 121 respectively. There are power ring 201 and ground ring 202 around the die 10. And there are normal signal finger 180, clock finger 181, first guard finger 182 and second guard finger 183 etc. around the ring 20, wherein first guard finger 182 and second guard finger 183 are formed between normal signal finger 180 and clock finger 181 respectively. Normal signal goes from normal signal pad 120 to normal signal finger 180 through normal signal bonding wire 140, and connects to corresponding solder ball 26 through normal signal trace 32. Similar to the transmitting of the normal signal, clock goes from clock pad 121 to clock finger 181 through clock bonding wire 141, and connects to corresponding solder ball 26 through clock trace 28. While the power pad 122 beside the clock pad 121 outputs a power signal to a power ring 201 through the power bonding wire 142, and connects the power ring 201 to the first guard finger 182 through the power bonding wire 142, then connects the first guard finger 182 to the edge of the substrate 16 through the power trace 301. The ground pad 123 beside the clock pad 121 outputs a ground signal to a ground ring 202 through the ground bonding wire 143, and connects the ground ring 202 to the second guard finger 183 through the ground bonding wire 143, then connects the second guard finger 183 to the edge of the substrate 16 through the ground trace 302. Take the power trace 301 for example, when the substrate 16 comprises a power plane 34 or a ground plane 36, as shown in FIG. 4b, the power trace 301 connects to the power plane 34 or a ground plane 36 of the substrate 16 through the via 241 at the edge of the substrate 16; if the substrate 16 comprises neither power plane 34 nor ground plane 36, as shown in FIG. 4c, the power trace 301 connects to the power solder ball 262 under the substrate 16 through the via 241 at the edge of the substrate 16. Thus, no matter the condition is FIG. 4b or FIG. 4c, the power trace 301 is a guard trace with both side shorted to ground. Likely, similar to the layout structure of FIG. 4b and FIG. 4c, the ground trace can be a guard trace with both side shorted to ground.

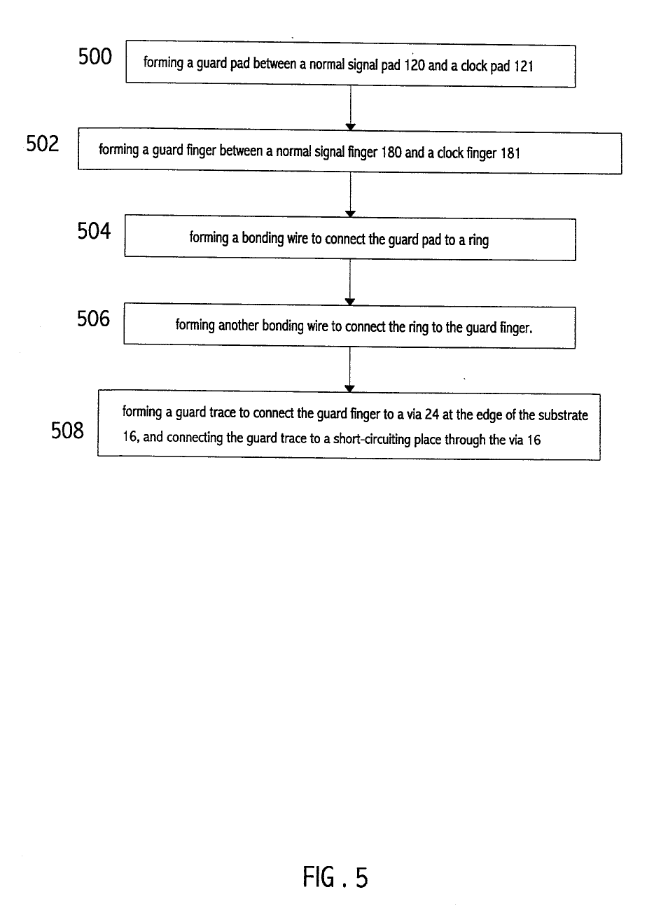

FIG. 5 is a flow chart of substrate layout method in FIG. 4a. First in step 500, a guard pad is formed between a normal signal pad 120 and a clock pad 121. The guard pad is selected from the group consisting of a power pad 122 and a ground pad 123. In step 502, a guard finger is formed between a normal signal finger 180 and a clock finger 181. According to the guard pad type, the guard finger is selected from the group consisting of a first guard finger 182 and a second guard finger 183. In step 504, a bonding wire is formed to connect the guard pad to a ring. According to the guard pad type, the bonding wire is selected from the group consisting of a power bonding wire 142 and a ground bonding wire 143, and the ring is selected from the group consisting of a power ring 201 and a ground ring 202. Then in step 506, another bonding wire is formed to connect the ring to the guard finger. Subsequently in step 508, a guard trace is formed to connect the guard finger to a via 24 at the edge of the substrate 16, and connect the guard trace to a short-circuiting place through the via 16. If there is a power plane 34 or a ground plane 36, the short-circuiting place is selected from the group consisting of a power plane 34 and ground plane 36 of the substrate 16; if there is no power plane 34 nor ground plane 36, the short-circuiting place is selected from the group consisting of a power and ground solder ball under the substrate 16.

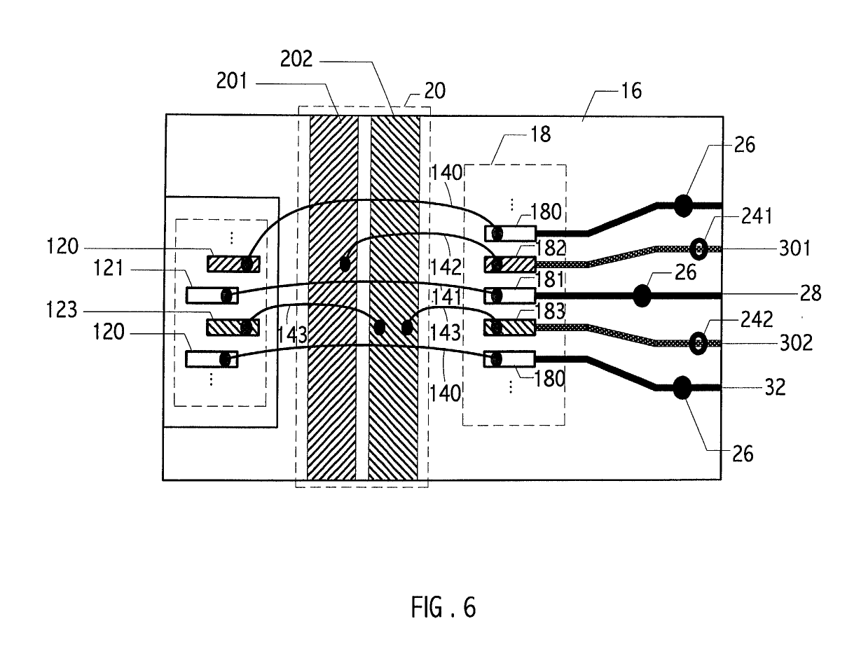

However, if there is neither power pad 122 nor ground pad 123 between the clock pad 121 and the normal signal pad 120, the layout method of BGA substrate is different from FIG. 4a. Refer to FIG. 6, FIG. 6 is a schematic diagram of another embodiment in accordance with this invention. The difference between FIG. 4a and FIG. 6 is that one side of the clock pad 121 is a normal signal pad 120 rather than a power pad or ground pad. Thus, the normal signal pad 120 directly connects to the normal signal finger 180 through the bonding wire 140, while the power bonding wire 142 for screening against cross talk directly connects the power ring 201 to the first guard finger 182, and then connects the first guard finger 182 to the edge of the substrate 16 through the power trace 301, subsequently connects to the power plane or the ground plane of the substrate 16 through the via 241 at the edge of the substrate 16. If there is neither power plane 34 nor ground plane 36, the power trace 301 connects to a power or ground solder ball under the substrate 16 through the via 241. Thus, the power trace 301 is a guard trace with both side shorted to ground. Consequently, if both side of the clock pad 121 are normal signal pad 120, only processing as the foregoing method can form a guard trace with both side shorted to ground between the clock trace 28 and the normal signal trace 32.

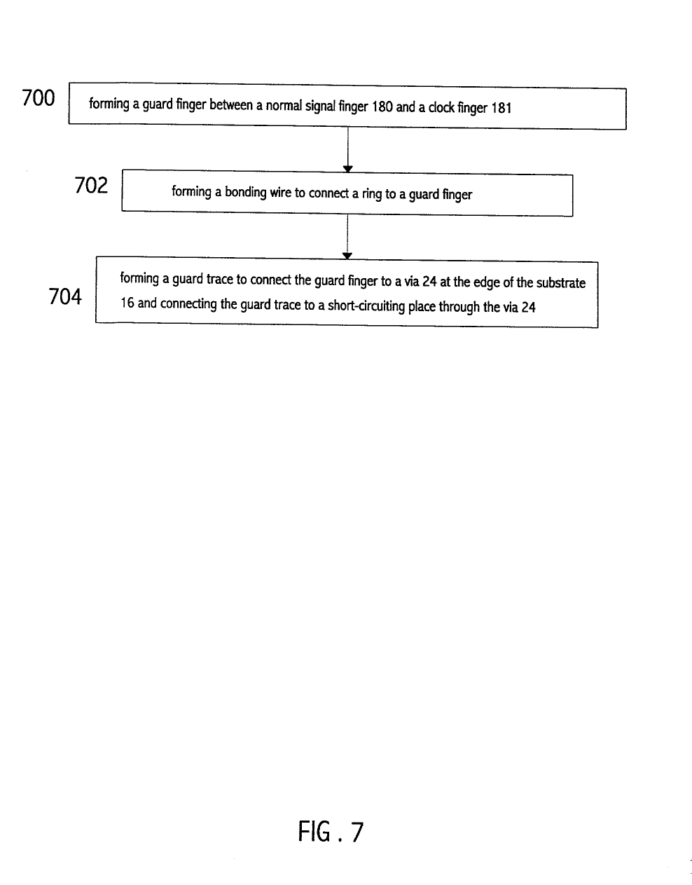

FIG. 7 is a flow chart of substrate layout method in FIG. 6. First in step 700, a guard finger is formed between the normal signal finger 180 and the clock finger 181. The guard finger is selected from the group consisting of a first guard finger 182 and a second guard finger 183. Second in step 702, a bonding wire is formed to connect a ring to the guard finger. The bonding wire is selected from the group consisting of a power bonding wire 142 and a ground bonding wire 143, and the ring is selected from the group consisting of a power ring 201 and a ground ring 202. Then in step 704, a guard trace is formed to connect the guard finger to a via 24 at the edge of the substrate 16 and connect the guard trace to a short-circuiting place through the via 24. If there is a power plane 34 or a ground plane 36, the short-circuiting place is selected from the group consisting of a power plane 34 and ground plane 36 of the substrate 16; if there is neither power plane 34 nor ground plane 36, the short-circuiting place is selected from the group consisting of a power and ground solder ball under the substrate 16.

According to FIG. 4 and FIG. 7, the present invention provides a substrate layout method and structure, not only reducing cross talk on the protected signal (usually the clock) due to adjacent signals, but also reducing cross talk on adjacent signals due to the protected signal.

While the invention has been described with reference to various illustrative embodiments, the description is not intended to be construed in a limiting sense. Various modifications of the illustrative embodiments, as well as other embodiments of the invention, will be apparent to those skilled in the art upon reference to this description. It is therefore contemplated that the appended claims will cover any such modifications or embodiments as may fall within the scope of the invention defined by the following claims and their equivalents.

What is claimed is:

1. A substrate layout method for reducing cross talk of adjacent signals, the substrate having a plurality of signal pads formed on a die, a ring around said die, and a plurality of signal fingers around said ring, the substrate layout method comprising:
forming a guard pad between two adjacent signal pads;
forming a guard finger between two adjacent signal fingers;
forming a first bonding wire to connect said guard pad to said ring;
forming a second bonding wire to connect said ring to said guard finger; and
forming a guard trace to connect said guard finger to a via at the edge of the substrate, and connecting said guard trace to a short-circuiting place through said via.

2. The substrate layout method as claimed in claim 1, wherein the substrate is a ball grid array.

3. The substrate layout method as claimed in claim 1, wherein said guard pad is selected from the group consisting of a power and ground pad.

4. The substrate layout method as claimed in claim 1, wherein said ring is selected from the group consisting of a power and ground ring.

5. The substrate layout method as claimed in claim 1, wherein said short-circuiting place is selected from the group consisting of a power and ground plane of the substrate.

6. The substrate layout method as claimed in claim 1, wherein said short-circuiting place is selected from the group consisting of a power and ground solder ball under the substrate.

7. A substrate layout structure for reducing cross talk of adjacent signals, the substrate having a plurality of signal pads formed on a die, a ring around said die, and a plurality of signal fingers around said ring, the substrate layout structure comprising:
a guard pad formed between two adjacent signal pads;
a guard finger formed between two adjacent signal fingers;
a first bonding wire for connecting said guard pad to said ring;
a second bonding wire for connecting said ring to said guard finger; and
a guard trace for connecting said guard finger to a via at the edge of the substrate, and connecting said guard trace to a short-circuiting place through said via.

8. The substrate layout method as claimed in claim 7, wherein the substrate is a ball grid array.

9. The substrate layout method as claimed in claim 7, wherein said guard pad is selected from the group consisting of a power and ground pad.

10. The substrate layout method as claimed in claim 7, wherein said ring is selected from the group consisting of a power and ground ring.

11. The substrate layout method as claimed in claim 7, wherein said short-circuiting place is selected from the group consisting of a power and ground plane of the substrate.

12. The substrate layout method as claimed in claim 7, wherein said short-circuiting place is selected from the group consisting of a power and ground solder ball under the substrate.

13. A substrate layout method for reducing cross talk of adjacent signals, the substrate having a plurality of signal pads formed on a die, a ring around said die, and a plurality of signal fingers around said ring, the substrate layout method comprising:
forming a guard finger between two adjacent signal fingers;
forming a bonding wire to connect said ring to said guard finger; and
forming a guard trace to connect said guard finger to a via at the edge of the substrate, and connecting said guard trace to a short-circuiting place through said via.

14. The substrate layout method as claimed in claim 13, wherein said ring is selected from the group consisting of a power and ground ring.

15. The substrate layout method as claimed in claim 13, wherein said short-circuiting place is a power and ground plane of the substrate.

16. The substrate layout method as claimed in claim 13, wherein said short-circuiting place is a power and ground solder ball under the substrate.

17. A substrate layout structure for reducing cross talk of adjacent signals, the substrate having a plurality of signal pads formed on a die, a ring around said die, and a plurality of signal fingers around said ring, the substrate layout structure comprising:
a guard finger formed between two adjacent signal fingers;
a bonding wire for connecting said ring to said guard finger; and
a guard trace for connecting said guard finger to a via at the edge of the substrate, and connecting said guard trace to a short-circuiting place through said via.

18. The substrate layout method as claimed in claim 17, wherein said ring is selected from the group consisting of a power and ground ring.

19. The substrate layout method as claimed in claim 17, wherein said short-circuiting place is selected from the group consisting of a power and ground plane of the substrate.

20. The substrate layout method as claimed in claim 17, wherein said short-circuiting place is selected from the group consisting of a power and ground solder ball under the substrate.
